(19) United States
(12) Patent Application Publication
(10) Pub. No.: US 2006/0131722 A1
(43) Pub. Date: Jun. 22, 2006

(54) Package and method for saving space required by I/O of chip

(75) Inventor: Yu-Wei Chyan, Hsinchu (TW)

Correspondence Address: BIRCH STEWART KOLASCH & BIRCH, PO BOX 747, FALLS CHURCH, VA, 22040-0747, US

(73) Assignee: SILICONMOTION INC.

(21) Appl. No.: 11/147,430

(22) Filed: Jun. 8, 2005

(30) Foreign Application Priority Data
Dec. 21, 2004 (TW) 93139884

(51) Int. Cl. H01L 23/48

(52) U.S. Cl. 257/690

(57) ABSTRACT

A package and a method for saving space required by I/Os of a chip are described. In this method, a plurality of general I/Os and at least one special I/O are allocated in different areas. When the chip is attached to a circuit board, the special I/O is adjacent to a non-soldering area of the circuit board and the general I/Os are adjacent to a soldering area of the circuit board. The special I/O is located on the bottom surface of the chip. When the chip is attached to the circuit board, the special I/O is adjacent to a soldering resistant layer and the general I/Os are electrically connected to signal lines on the circuit board.

### RELATED APPLICATIONS

The present application is based on, and claims priority from, Taiwan Application Serial Number 93139884, filed Dec. 21, 2004, the disclosure of which is hereby incorporated by reference herein in its entirety.

### BACKGROUND

1. Field of Invention

The present invention relates to a chip package and a packaging method. More particularly, the present invention relates to a chip package and a packaging method that save space required by the I/Os of a chip.

2. Description of Related Art

With the development of electronics engineering, a complex circuit can be integrated into a chip. The required I/O pin number increases with the increasing complexity of a chip. However, the dimension and the area of a chip are becoming smaller and smaller because of new generation fabrication techniques. A great number of I/O pins extending from a chip that has a very small area may cause problems in soldering and may lead to a lower yield. The extremely close pins may incur errors when the chip is in operation. The chip may fail because of these problems. An overly crowded pin arrangement may also increase difficulty in designing a circuit board.

FIG. 1 is a bottom view of a package of a chip in prior art. With reference to FIG. 1, the package is an LGA (land grid array) package. The package has 20 pins 1-20. Among the pins 1-20, 4 pins (pin 17-20) are used only for testing. The test pins 17-20 need not be soldered to a circuit board. However, the test pins are lined up with other general pins 1-16 on the edge of the package. The distance 102 is too small. When the chip needs a lot of pins, the density of the pins become too high and the design of circuit board will be difficult.

### SUMMARY

It is therefore an objective of the present invention to provide a method for saving space required by the I/Os of a package, which method reduces the number of pins in the soldering area of a circuit board.

It is another objective of the present invention to provide a method for saving space required by the I/Os of a package, which method increases the distance between pins, whereby a good yield is achieved without a very delicate soldering.

It is still another objective of the present invention to provide a package for saving space required by the I/Os of a chip, in which the package reduces the number of pins in the soldering area of a circuit board.

It is still another objective of the present invention to provide a package for saving space required by the I/Os of a chip, in which the package increases the distance between the pins, whereby a good yield is achieved without a very delicate soldering.

It is still another objective of the present invention to provide a package for saving space required by the I/Os of a chip, in which the package obtains a bigger distance between pins and can accommodate more I/Os needing to connect to the circuit board.

In accordance with the foregoing and other objectives of the present invention, a method for saving space required by I/Os of a package is described. The method includes the following steps. A plurality of general I/Os and at least one special I/O are allocated into different areas of a package of a chip. When the chip is attached to a circuit board, the special I/O is placed adjacent to a non-soldering area of the circuit board, and the general I/Os are placed adjacent to a soldering area of the circuit board.

The special I/O is, for example, a test pin or an extension pin. The special I/O can be placed on the bottom surface of the chip. When the chip is attached to a circuit board, the bottom surface of the chip is adjacent to the soldering resistant layer of the circuit board, and the general I/Os are electrically connected to the corresponding signal lines, power lines, and grounding lines of the circuit board.

In accordance with the foregoing and other objectives of the present invention, a package for saving space required by I/Os is described. According to one embodiment of the invention, the package includes a package layer, a plurality of general I/Os, and at least one special I/O. The package layer covers a chip. The general I/Os connect to the chip through the package layer. The special I/O also connect to the chip through the package. The general I/Os and the special I/O are allocated into different areas on the surface of the package. When the chip is attached to a circuit board, the special I/O is placed adjacent to a non-soldering area of the circuit board, and the general I/Os are placed adjacent to a soldering area of the circuit board.

The special I/O is, for example, a test pin or an extension pin. The test pin can be placed on the bottom surface of the package layer. When the chip is attached to the circuit board, the bottom surface of the package layer is adjacent to the soldering resistant layer of the circuit board, and the general I/Os are electrically connected to the signal lines of the circuit board.

The invention has at least the following advantages. Each embodiment can present one or more of the advantages. The method for saving space required by the I/Os of a package can reduce the number of pins in the soldering area of a circuit. The method for saving space can increase the distance between pins and a good yield can be achieved without a very delicate soldering. The package for saving space can reduce the number of pins in the soldering area of a circuit board. The package for saving space can increase the distance between pins and a good yield can be achieved without a very delicate soldering. With the same package dimensions, the invention can obtain a bigger distance between pins and can accommodate more I/Os that need to connect to the circuit board.

It is to be understood that both the foregoing general description and the following detailed description are examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a bottom view of a package of a chip in the prior art;

FIG. 2 is a diagram illustrating an embodiment of the invention;

FIG. 3 is a diagram illustrating a soldering area and a non-soldering area on a circuit board according to the present invention; and

FIG. 4 is a diagram illustrating a soldering area and a non-soldering area on a circuit board according to the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

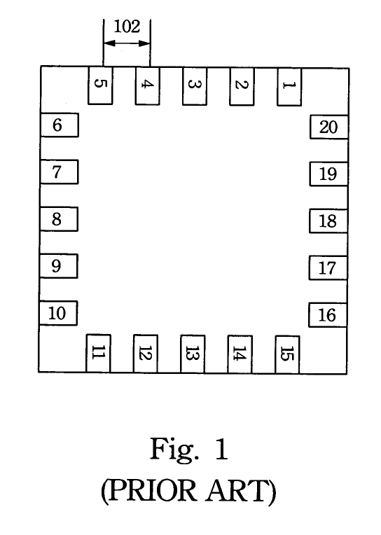

FIG. 1 is a bottom view of a package of a chip in prior art. With reference to FIG. 1, the package is an LGA (land grid array) package. The package has 20 pins 1-20. Among the pins 1-20, 4 pins (pin 17-20) are used only for test. The test pins 17-20 need not be soldered to a circuit board. However, the test pins are lined up with other general pins 1-16 on the edge of the package. The distance 102 is too small. When the chip needs a lot of pins, the density of the pins become too high and the design of circuit board will be difficult.

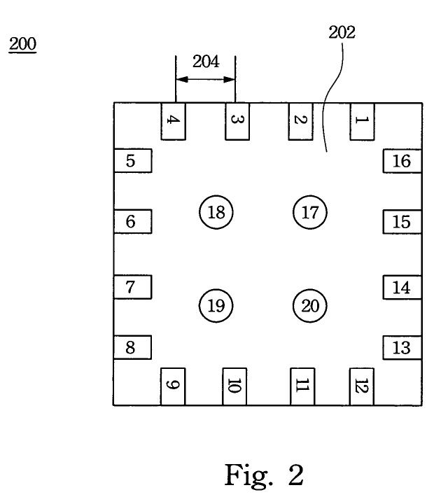

FIG. 2 is a diagram illustrating an embodiment of the invention. FIG. 2 is a bottom view of a package 200 that can save space required by the I/Os. The package 200 includes a package layer 202, a plurality of general I/Os 1-16, and special I/Os 17-20. The package layer 202 covers a chip (not shown). The general I/Os 1-16 connect to the chip through the package layer 202. The special I/Os 17-20 connect to the chip through the package layer 202. The general I/Os connect to signal lines, power lines, and grounding lines of a circuit board. I/Os, except for the general I/Os, are called the special I/Os.

The general I/Os 1-16 and the special I/Os 17-20 are allocated into different areas on the surface of the package layer 202. When the chip is attached to a circuit board, the special I/Os are placed adjacent to the non-soldering area of the circuit board, and the general I/Os are placed adjacent to a soldering area of the circuit board.

As shown in FIG. 1, in the embodiment, the general I/Os 1-16 are placed around the edge of the surface of the package layer 202, and the special I/Os are placed on the bottom surface of the package layer 202. The bottom surface of the package layer 202 will be attached to a non-soldering area or a soldering area of a circuit board. Therefore, the special I/Os 17-20 and the circuit board are electrically insulated. Only the general I/Os 1-16 can electrically connect to the circuit board to exchange signals or to obtain a working voltage. When the chip is attached to the circuit board, the general I/Os 1-16 connect to the corresponding signal lines, power lines, and grounding lines of the circuit board.

In one embodiment, the special I/Os 17-20 are test pins. The test pins 17-20 are used only for testing. When the chip is attached to the circuit board, the test pins are no longer needed. In this embodiment, the test pins 17-20 do not occupy the space around the edge of the package layer 202. Thus, a bigger distance 204 around the edge of the package layer 202 is provided. Therefore, a very delicate soldering is not needed. The yield can also be improved.

In another embodiment, the special I/Os are extension pins. Extension pins are prepared for a future application, but not needed for a present application. In the present application, the extension pins need not electrically connect to the circuit board, so the extension pins can be placed adjacent to the non-soldering area of the circuit board. The extension pins 17-20 will not occupy the space around the edge of the package layer 202. A bigger distance 204 is obtained around the edge of the package layer 202. Thus, a very delicate soldering is not needed. The yield can also be improved.

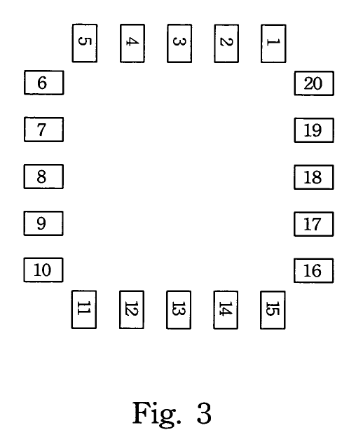

FIG. 3 is a diagram illustrating a soldering area and a non-soldering area on a circuit board. The package shown in FIG. 1 can be soldered to the circuit board shown in FIG. 3. In FIG. 3, the area on which the I/Os 1-20 are placed is a soldering area of the circuit board. The other area represents a non-soldering area of the circuit board. The soldering area is used to electrically connect to the chip. There is a soldering resistant layer on the non-soldering area to prevent soldering. In FIG. 3, the distance is small and the circuit board needs more delicate soldering. Thus, the yield will be lower.

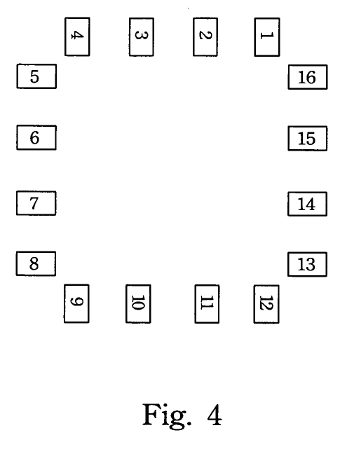

FIG. 4 is a diagram illustrating a soldering area and a non-soldering area on a circuit board. The package shown in FIG. 2 can be soldered to the circuit board shown in FIG. 4. In FIG. 4, the area on which the I/Os 1-16 are placed is a soldering area of the circuit board. The other area represents a non-soldering area of the circuit board. The soldering area is used to electrically connect to the chip. There is a soldering resistant layer on the non-soldering area to prevent soldering. Compared to FIG. 3, the distance in FIG. 4 is bigger and the circuit board doesn't need very delicate soldering. Thus, the yield will be higher. In this situation, the chip can be designed to have more I/Os in the soldering area, and therefore the designs of the circuit board and the chip have more flexibility.

In the embodiment, the number of the general I/Os and the number of the special I/Os are just examples and are not intended to limit the scope of the invention. The LGA is also an example and is not intended to limit the package application of the invention. Other packages can also benefit from the invention. The I/Os that are no longer needed can be placed in the non-soldering area of the circuit board to reduce the pin density in a soldering area, to increase the distance between pins, and to improve the yield.

The invention also discloses a method for saving space required by the I/Os of a package. The method includes the following steps. A plurality of general I/Os and at least one special I/O of a chip are allocated in different areas. When the chip is attached to a circuit board, the special I/O is placed adjacent to a non-soldering area of the circuit board, and the general I/Os are placed adjacent to a soldering area of the circuit board. The special I/O is, for example, a test pin or an extension pin.

In one embodiment, the special I/O is on the bottom surface of the chip. When the chip connects to the circuit board, the bottom surface of the chip is adjacent to the soldering resistant layer of the circuit board, and the general I/Os are electrically connected to the signal lines of the circuit board.

The invention has at least the following advantages. Each embodiment can present one or more of the advantages. The method for saving space required by the I/Os of a package can reduce the number of pins in the soldering area of a circuit. The method for saving space can increase the distance between pins and a good yield can be achieved without a very delicate soldering. The package for saving space can reduce the number of pins in the soldering area of a circuit board. The package for saving space can increase the distance between pins and a good yield can be achieved without a very delicate soldering. With the same package dimensions, the invention can obtain a bigger distance between pins and can accommodate more I/Os that need to connect to the circuit board.

Although the present invention has been described in considerable detail with reference to certain preferred embodiments thereof, other embodiments are possible. Therefore, their spirit and scope of the appended claims should no be limited to the description of the preferred embodiments container herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for saving space required by I/Os of a package, the method comprising:
allocating a plurality of general I/Os and at least one special I/O in different areas of a package of a chip; and
when the chip is attached to a circuit board, placing the special I/O adjacent to a non-soldering area of the circuit board, and placing the general I/Os adjacent to a soldering area of the circuit board.

2. The method of claim 1, wherein the at least one special I/O is a test pin.

3. The method of claim 1, wherein the at least one special I/O is an extension pin.

4. The method of claim 1, wherein the at least one special I/O is located on a bottom surface of the chip, and when the chip is attached to the circuit board, the bottom surface of the chip is adjacent to a soldering resistant layer of the circuit board.

5. The method of claim 1, wherein when the chip is attached to the circuit board, the general I/Os are connected to corresponding signal lines, power lines, and grounding lines of the circuit board.

6. A package for saving space required by I/Os, the package comprising:
a package layer for covering a chip;
a plurality of general I/Os, connecting to the chip through the package; and
at least one special I/O, connecting to the chip through the package;
wherein the general I/Os and the special I/O are allocated in different areas on the surface of the package, and when the chip is attached to a circuit board, the special I/O is placed adjacent to a non-soldering area of the circuit board, and the general I/Os are placed adjacent to a soldering area of the circuit board.

7. The package of claim 6, wherein the at least one special I/O is a test pin.

8. The package of claim 6, wherein the at least one special I/O is an extension pin.

9. The package of claim 6, wherein the at least one special I/O is located on a bottom surface of the chip, and when the chip is attached to the circuit board, the bottom surface of the chip is adjacent to a soldering resistant layer of the circuit board.

10. The package of claim 6, wherein when the chip is attached to the circuit board, the general I/Os are connected to corresponding signal lines, power lines, and grounding lines of the circuit board.
